(19) United States
(12) Patent Application Publication
(10) Pub. No.: US 2014/0076382 A1
(43) Pub. Date: Mar. 20, 2014

(54) PHOTOVOLTAIC MODULE AND PROCESS FOR MANUFACTURE THEREOF

(71) Applicant: PETROS DAFNIOTIS, Geneva (CH)

(72) Inventor: PETROS DAFNIOTIS, Geneva (CH)

(73) Assignee: E I DU PONT DE NEMOURS AND COMPANY, Wilmington, DE (US)

(21) Appl. No.: 14/031,428

(22) Filed: Sep. 19, 2013

Related U.S. Application Data
(60) Provisional application No. 61/703,425, filed on Sep. 20, 2012.

(51) Int. Cl. H01L 31/05; H01L 31/18; H01L 31/048

(52) U.S. Cl. CPC H01L 31/0516; H01L 31/048; H01L 31/1876
USPC 136/251; 438/67

(57) ABSTRACT

A photovoltaic module has a plurality of interconnected polymer sockets that have accepted and electrically connected a plurality of back-contact photovoltaic cells each having at least one set of linearly arranged backface emitter contacts and at least one set of linearly arranged backface collector contacts. A process for manufacturing such a photovoltaic module is also provided.

### FIELD OF THE INVENTION

The present invention relates to a photovoltaic module comprising a plurality of concatenated polymer sockets, each polymer socket having accepted and electrically connected a back-contact photovoltaic cell. The invention also relates also to a process for the manufacture of such a photovoltaic module.

### BACKGROUND OF THE INVENTION

Photovoltaic cells, sometimes called solar cells or photoactive cells, can convert light, such as sunlight, into electrical energy.

In practice, a plurality of photovoltaic cells is electrically connected together in series or in parallel to form an array of photovoltaic cells which can be incorporated into a photovoltaic module.

In order to increase the voltage delivered by individual photoactive cells to a suitable level, the cells are conventionally connected in series.

A serial connection between the cells of a module can be achieved by connecting the emitter contact of one photovoltaic cell to the collector contact of the next (adjacent) cell, usually by soldering an electrical conductor such as wire, tape or ribbon to the contacts of adjacent cells.

In most of today's photovoltaic modules, the photovoltaic cells that convert light into electrical energy are H-type cells, in which the emitter contacts and collector contacts are located on opposite sides of the cells. The emitter contacts are located on the front surface, i.e. the surface exposed to the sunlight, whereas the collector contacts are on the back side. FIG. 1A shows the frontface of an H-type photovoltaic cell E having two emitter contacts (D1, D2), also known as emitter bus bars. FIG. 1B shows the backface of an H-type photovoltaic cell E having two collector contacts (F1, F1), also known as collector bus bars. A skilled person will recognize that emitter contacts and collector contacts are of opposite polarity.

The electrical conductors connecting two cells are soldered such that the front emitter contacts of one photovoltaic cell are connected with one or more back collector contacts of the adjacent photovoltaic cell. On an industrial scale, the electrical conductors are applied to the cell contacts by way of automated soldering equipment (so-called “tabber-stringer”).

However, when soldered to the front emitter contacts, the electrical conductors cover a portion of the available photovoltaic surface of the cell, which in turn reduces the amount of electrical energy that can be produced by the cell.

New cell types have been developed in which the emitter contacts have been moved from the front face to the back face of the photovoltaic cell in order to free up an additional portion of front surface and increase the amount of electrical energy that can be produced by the cell.

Such photovoltaic cells, in which both emitter and collector contacts are located on the back side of the cell, are known under the common designation “back-contact cells”, which designation encompasses metallization wrap-through (MWT) cells, back-junction (BJ) cells, integrated back-contact (IBC) cells and emitter wrap-through (EWT) cells.

Moving from traditional H-type cells having front emitter contacts to back-contact cells having back emitter contacts requires drastic changes in the structure of the photovoltaic module itself, such as for example a complete redesign of the electrical connections between the cells. Concurrently, these structural changes in the photovoltaic module also require a redesign of the manufacturing equipment as well as changes in the module manufacturing method.

WO2006/123938 describes a method of contacting MWT cells by tabbing and stringing. However, the proposed method requires the use of extensive amounts of an insulating material, which is economically discouraging. Furthermore, applying significant amounts of insulating material as well as the electrical conductors on the rear side of a cell creates local unevenness that will warp the cell during the lamination step of module production. The warpage induces mechanical strains in the cell, which results in a lessened degree of efficiency, and also results in the formation of cracks.

The above described changes make the purchase of new manufacturing equipment inevitable for a module manufacturer desiring to use back-contact cells, which presents a considerable economic hurdle for the adoption of back-contact cells in photovoltaic modules. It would therefore be desirable to provide for a means that allows the manufacturing of photovoltaic modules incorporating back-contact cells, but without the need of entirely replacing or considerably altering existing manufacturing equipment and thus make the change more economically feasible.

### SUMMARY OF THE INVENTION

The present invention provides for a photovoltaic module comprising a front sheet, a front encapsulant layer, a plurality of concatenated polymer sockets (i.e. a plurality of concatenations of polymer sockets), each polymer socket having accepted and electrically connected a back-contact photovoltaic cell, each back-contact photovoltaic cell having at least one set of linearly arranged backface emitter contacts and at least one set of linearly arranged backface collector contacts, an optional back encapsulant layer, and a back sheet. Each polymer socket comprises a planar, electrically insulating polymer substrate comprising perforations coinciding with the backface emitter contacts, and at least one electrical conductor being collinear with the perforations of the planar substrate and being adhered to the backface of the planar polymer substrate. The at least one electrical conductor of each polymer socket, except the last one in each row, is adhered to the frontface of the planar substrate of one adjacent polymer socket, so as to be collinear with the at least one set of linearly arranged backface collector contacts of the back-contact photovoltaic cell accepted and electrically connected by the adjacent polymer socket. The back-contact photovoltaic cells accepted and electrically connected by adjacent polymer sockets are rotated by 180° with respect to each other.

The present invention further provides for a process for the manufacture of a photovoltaic module comprising the steps of assembling a stack by placing an optional back encapsulant layer on a back sheet, placing a plurality of concatenated polymer sockets, each polymer socket having accepted and electrically connected a back-contact photovoltaic cell, on top of the optional back encapsulant layer, placing a front encapsulant layer on top of the back-contact photovoltaic cells and then placing a front sheet on top of the front encapsulant layer. The so assembled stack is consolidated in a laminating device by heating the stack to a temperature of from 100 to 225° C. and subjecting the heated stack to a mechanical pressure in a direction perpendicular to the plane of the stack and decreasing the ambient pressure in the laminating device to 300 to 1200 mbar, and then cooling the stack to ambient temperature and releasing the mechanical pressure and reestablishing atmospheric pressure in the laminating device. The back-contact photovoltaic cells accepted and electrically connected by adjacent polymer sockets are rotated by 180° with respect to each other.

### BRIEF DESCRIPTION OF THE DRAWINGS

FIG. 1A shows the frontface of an H-type photovoltaic cell.

FIG. 1B shows the backface of an H-type photovoltaic cell.

FIG. 2 shows the frontface of a MWT photovoltaic cell.

FIG. 3 shows the backface of a MWT photovoltaic cell.

FIG. 4 shows an exploded view of a plurality of MWT photovoltaic cells and a plurality of polymeric sockets electrically interconnected to form a concatenation of interconnected polymer sockets and photovoltaic cells.

FIG. 5A shows the frontface of a planar, electrically insulating polymer substrate of a polymeric socket.

FIG. 5B shows a cross-sectional side view of the electrically insulating polymer substrate of FIG. 5A.

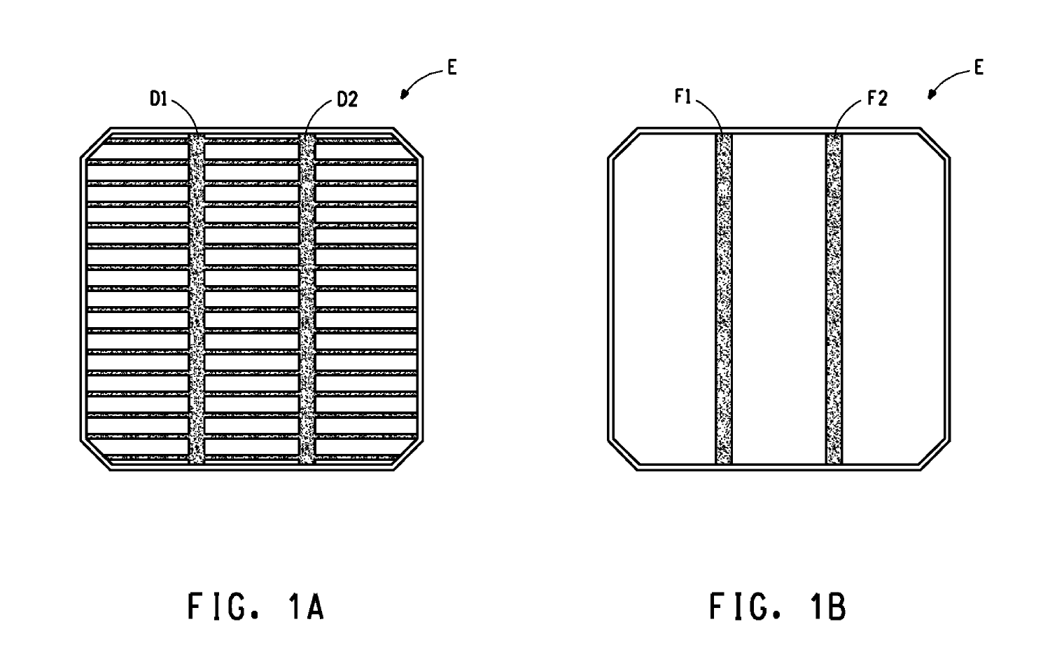

### DETAILED DESCRIPTION

For the purpose of the present disclosure, the term “backface” or “back” denotes the surface of a photovoltaic cell in a photovoltaic module, or of any other planar element in a photovoltaic module, such as in particular the polymer sockets of the photovoltaic module of the present invention, which faces away from incident light, i.e. which faces towards the back sheet of the photovoltaic module.

For the purpose of the present disclosure, the term “frontface” or “front” denotes the surface of a photovoltaic cell in a photovoltaic module, or of any other planar element in a photovoltaic module, such as in particular the polymer sockets of the photovoltaic module of the present invention, which faces towards incident light, i.e. which faces away from the back sheet and towards the front sheet of the photovoltaic module.

For the purpose of the present disclosure, the term “light” means any type of electromagnetic radiation that can be converted into electric energy by a photovoltaic cell.

For the purpose of the present disclosure, the terms “photoactive” and “photovoltaic” may be used interchangeably and refer to the property of converting radiant energy (e.g., light) into electrical energy.

For the purpose of the present disclosure, the terms “photovoltaic cell” or “photoactive cell” means an electronic device that can convert electromagnetic radiation (e.g., light) into an electrical signal. A photovoltaic cell includes a photoactive material layer that may be an organic or inorganic semiconductor material that is capable of absorbing radiation and converting it into electrical energy. The terms “photovoltaic cell” or “photoactive cell” are used herein to include solar cells with any types of photoactive layers including crystalline silicon, amorphous silicon, cadmium telluride, and copper indium gallium selenide (GIGS) photoactive layers.

For the purpose of the present disclosure, the term “photovoltaic module” (also “module” for short) means any electronic device having at least one photovoltaic cell.

For the purpose of the present disclosure, the term “encapsulant layer” refers to a layer of material that is designed to protect the photoactive cells from degradation caused by chemical and/or mechanical stress.

For the purpose of the present disclosure, the term “front encapsulant layer” refers to an encapsulant layer that is located between the frontface of a photoactive cell and the front sheet of the module.

For the purpose of the present disclosure, the term “back encapsulant layer” refers to an encapsulant layer that is located between the backface of a photoactive cell and the back sheet of the module.

For the purpose of the present disclosure, the term “ionomer” means and denotes a thermoplastic resin containing both covalent and ionic bonds derivable from ethylene copolymers. Ionomers may be obtained by partial neutralization of ethylene-methacrylic acid copolymers or ethylene-acrylic acid copolymers with inorganic bases having cations of elements from Groups I, II, or III of the Periodic table, notably, sodium, aluminum, lithium, magnesium, and barium may be used, or transition metals such as zinc. The term “ionomer” and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical Properties And Structural Features Of Surlyn lonomer Resins”, Polyelectrolytes, 1976, C, 177-197.

For the purpose of the present disclosure, the term “emitter contact” means and denotes an electrical contact connecting the emitter of a photovoltaic cell to an electrical conductor. In the case of a back-contact photovoltaic cell such as MWT cells, the emitter contacts are the so-called “vias”, or “back emitter contacts”, located on the backface of the cell.

For the purpose of the present disclosure, the term “collector contact” means and denotes an electrical contact connecting the collector of a photovoltaic cell to an electrical conductor. In the case of a back-contact photovoltaic cell such as MWT cells, the collector contacts are located on the backface of the cell.

For the purpose of the present disclosure, the term “concatenation” refers to an unbranched, row-like assembly of two or more elements.

For the purpose of the present disclosure, the term “collinear” refers to a collinear relationship, when viewed along the direction normal to the plane defined by the polymer substrate of the polymer socket.

The present invention provides for a photovoltaic module comprising a front sheet, a front encapsulant layer, a plurality of concatenated polymer sockets, each polymer socket having accepted and electrically connected a back-contact photovoltaic cell, an optional back encapsulant layer, and a back sheet. Each back-contact photovoltaic cell has at least one set of linearly arranged backface emitter contacts and at least one set of linearly arranged backface collector contacts. Each polymer socket comprises a planar, electrically insulating polymer substrate comprising perforations coinciding with the backface emitter contacts, and at least one electrical conductor being collinear with the perforations of the planar substrate and being adhered to the backface of the planar polymer substrate. The at least one electrical conductor of each polymer socket, except the last one in each row, is adhered to the frontface of the planar substrate of one adjacent polymer socket, so as to be collinear with the at least one set of linearly arranged backface collector contacts of the back-contact photovoltaic cell accepted and electrically connected by said one adjacent polymer socket. The back-contact photovoltaic cells accepted and electrically connected by adjacent polymer sockets are rotated by 180° with respect to each other.

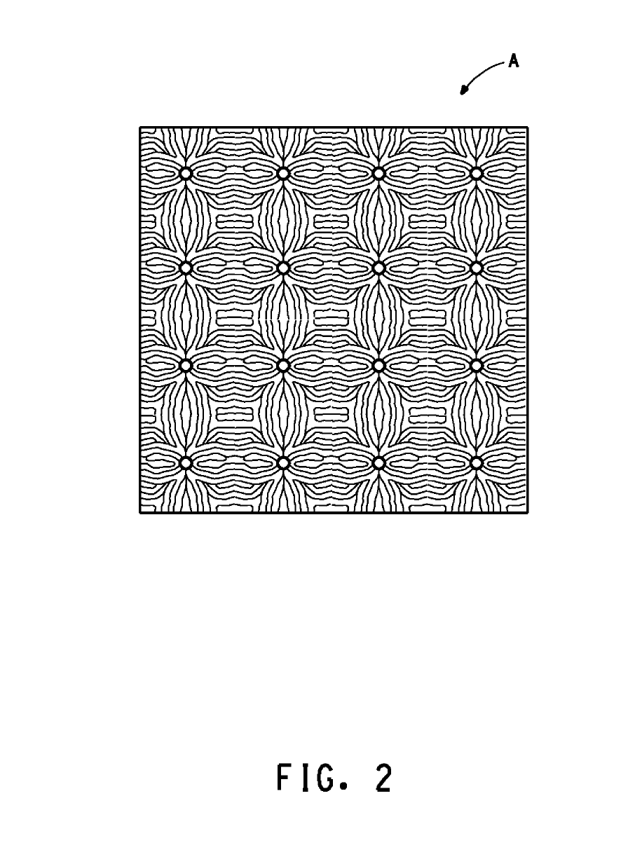

FIG. 2 shows the frontface of a MWT photovoltaic cell A. The lines that can be seen on the surface of the MWT back-contact photovoltaic cell are emitter contact lines comprised of a conductive material such as silver. The lines connect to a pluralitiy of spaced electrical vias that can be seen in FIG. 2 and which connect through the photovoltaic cell to backface emitter contacts on the back of the cell.

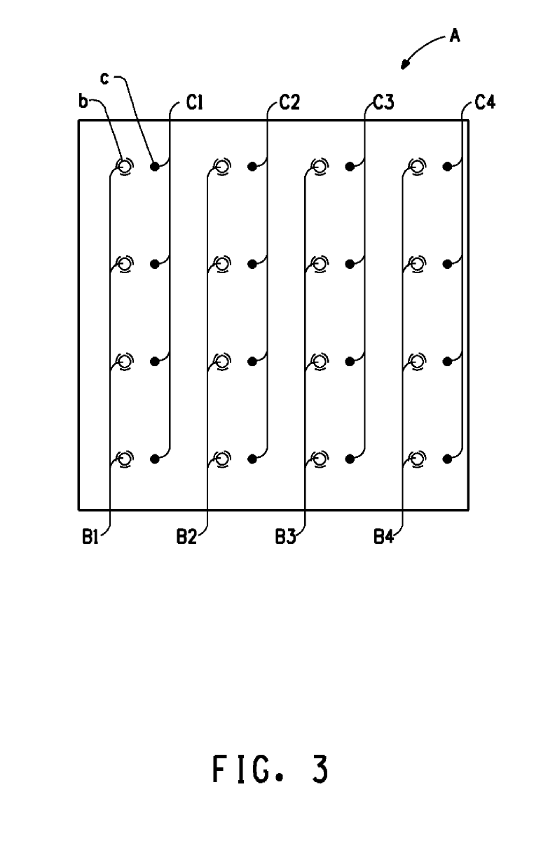

FIG. 3 shows the backface of a MWT photovoltaic cell A having four sets (B1, B2, B3, B4) of linearly arranged backface emitter contacts b and four sets (C1, C2, C3, C4) of linearly arranged backface collector contacts c.

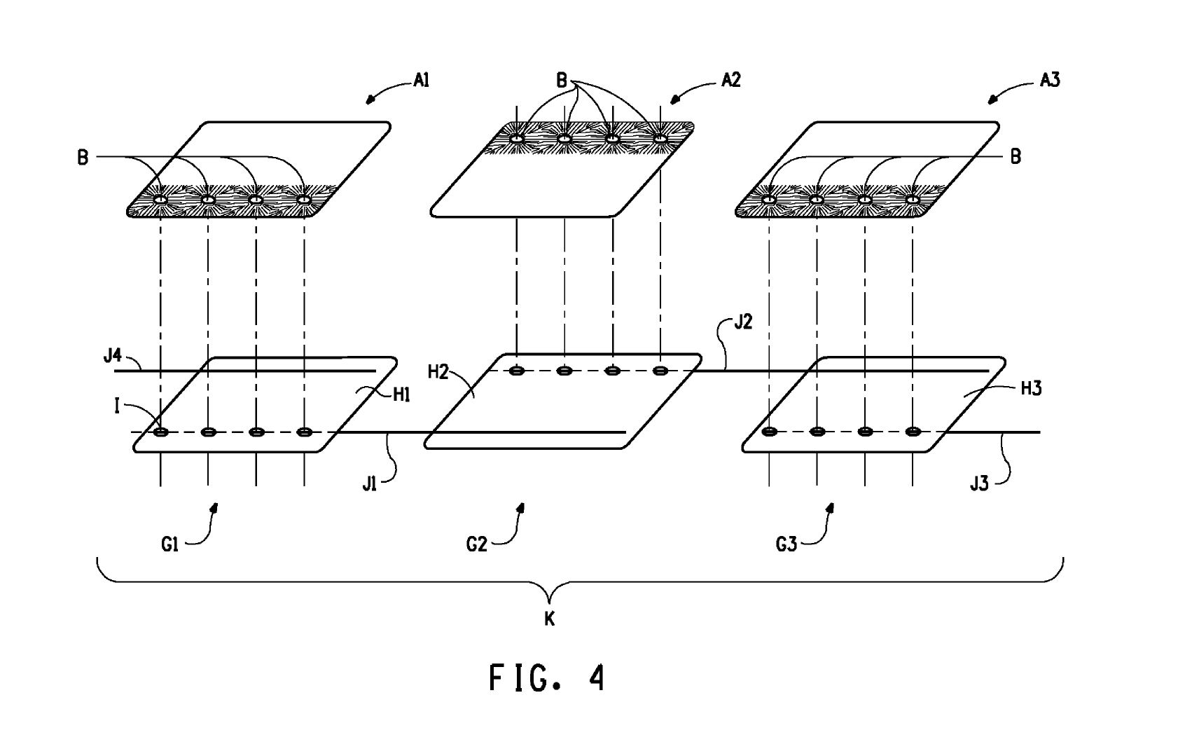

FIG. 4 shows an illustrative embodiment with a plurality of MWT photovoltaic cells (A1, A2, A3) of a back-contact photovoltaic module. A plurality of polymeric sockets (G1, G2, G3) comprising planar, electrically insulating polymer substrates (H1, H2, H3) are provided on the back side of each of the MWT cells. The polymeric sockets (G1, G2, G3) have perforations I coinciding with a set of linearly arranged backface emitter contacts (B) of the MWT photovoltaic cells to be accepted by the corresponding sockets.

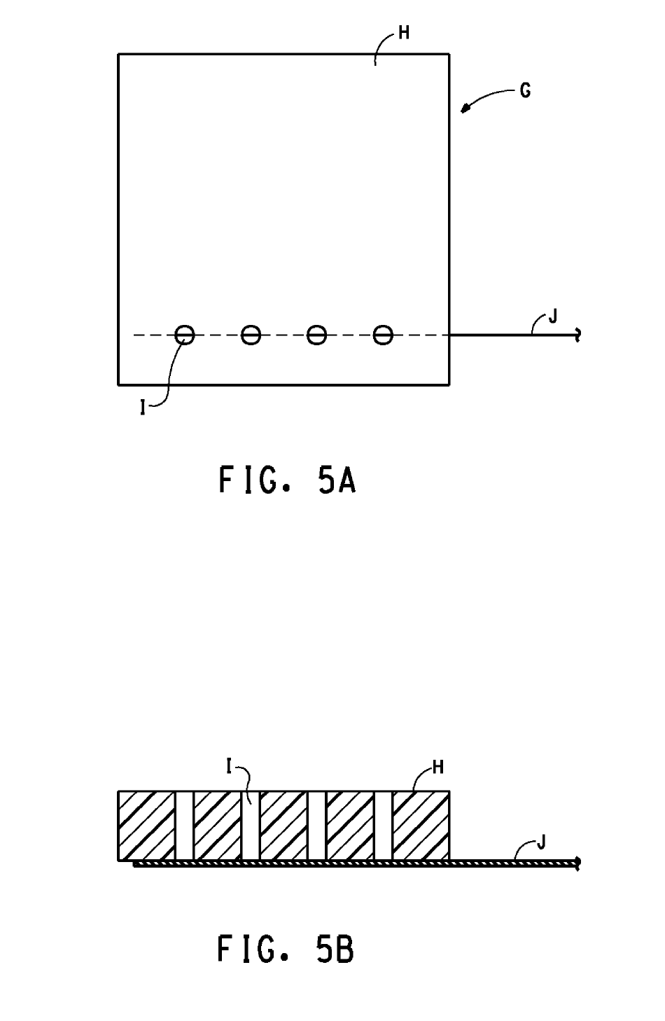

FIG. 5A shows the frontface of a planar, electrically insulating polymer substrate H of a polymeric socket G having perforations I to coincide with a row of linearly arranged backface emitter contacts of a MWT photovoltaic cell to be accepted by the socket. An electrical conductor J is collinear with the perforations I and is adhered to the backface of the polymer substrate. FIG. 5B shows a cross-sectional side view of the electrically insulating polymer substrate H along the electrical conductor J. The substrate has perforations I, and the conductor J is shown adhered to the backface of the polymer substrate H.

As shown in FIG. 4, the polymer substrates and MWT cells are interconnected by the electrical conductors (J1, J2, J3, J4) to form a concatenation K of interconnected polymer sockets. The backface emitter contacts of a first cell A1 are electrically connected to the conductor J1 through the perforations I in the polymer substrate. The backface emitter contacts of a first cell A1 are electrically connected to the backface collector contacts of the adjacent cell A2 via the conductor J1. The conductor is collinear with the perforations I coinciding with the set of linearly arranged backface emitter contacts of the MWT cells and the set of linearly arranged backface collector contacts of the MWT photovoltaic cell to be accepted and electrically connected by the adjacent polymer socket. For illustrative purposes, FIG. 4 shows photovoltaic MWT cells with just one row of emitter contacts and just one row of collector contacts, but it is contemplated that back-contact photovoltaic cells with multiple rows of emitter contacts and collector contacts, like the cell shown in FIG. 3, can be electrically connected with polymeric sockets having a corresponding number of electrical conductors.

The photovoltaic module of the present invention comprises a front sheet. The function of the front sheet is to provide a transparent protective layer that will allow incident light (e.g., sunlight) to reach the frontface of the back-contact photovoltaic cells comprised in the module. In general, the front sheet material may be of any material that provides protection against the elements for the module while also providing transparency to the incident light. The front sheet may be made of a rigid material, such as a glass, polycarbonate, acrylate polymer such as polymethylmethacrylate (PMMA) material, or a more flexible material, such as a fluoropolymer like for example polyvinyl fluoride (PVF), a polyvinylidene fluoride (PVDF), an ethylene tetrafluorethylene (ETFE) polymer, a perfluoroalkoxy vinyl polymer (PFA), an FEP (fluorinated ethylene propylene) copolymer of tetrafluoroethylene (TFE) and hexafluoropropylene (HFP), or a combination thereof. The front sheet may be a single layer of material, or may include more than one layer of the same or different materials.

The photovoltaic module according to the present invention also comprises a front encapsulant layer. The front encapsulant layer in the photovoltaic module according to the present invention may comprise any material as is conventional in the art of photovoltaic modules, i.e. the front encapsulant layer may comprise various transparent polymeric materials. The thickness of the front encapsulant layer may be in the range of, for example, 100 to 2000 μm, preferably of from 200 to 1000 μm, as is conventional for front encapsulant layers in photovoltaic modules.

The front encapsulant layer of the photovoltaic module according to the present invention is located adjacent to and between the front sheet and the frontface of the back-contact photovoltaic cells. The front encapsulant layer is designed to encapsulate and further protect the frontface of the back-contact photovoltaic cells from environmental degradation and mechanical damage, but at the same time is required to have excellent transparency that allows a maximum of incident light to reach the frontface of the photoactive cells, and also bonds the photoactive cells to the front sheet.

Preferably, the front encapsulant layer comprises ethylene vinyl acetate copolymer, polyvinyl butyral, ethylene alkyl(meth)acrylate copolymer, thermoplastic polyurethane, ionomer, and/or any combinations thereof. More preferably, the front encapsulant layer comprises an ionomer, and preferably comprises a blend of a first ionomer and a second ionomer different from the first ionomer or a blend of a first ionomer and an non-neutralized copolymer of ethylene and (meth)acrylic acid. In the case where the front encapusant layer comprises an ionomer or a blend of ionomers, the ionomers are preferably chosen from ionomers that comprise from 8 wt % to 25 wt % of an ethylenically unsaturated, C3 to C8 carboxylic acid, and optionally comprise from 10 wt % to 20 wt % of an alkyl acrylate, based on the total weight of the ionomer.

Suitable ionomers and blends of a first ionomer and a second ionomer are further described in European patent EP1781735, which is hereby incorporated by reference. In the case where the front encapsulant layer comprises a blend of a first ionomer and a non-neutralized copolymer of ethylene and (meth)acrylic acid, the non-neutralized copolymer of ethylene and (meth)acrylic acid preferably comprises of from 2 to 15 weight percent, more preferably of from 2 to 9 weight percent of (meth)acrylic acid, based on the total weight of the non-neutralized copolymer of ethylene and (meth)acrylic acid.

The front encapsulant layer can include more than one layer of encapsulant material, wherein each layer may include the same encapsulant material or a different encapsulant material from the other layer(s).

The front encapsulant layer may further comprise UV stabilization additives to prevent UV degradation of the encapsulant, but such additives are preferably not included in the front encapsulant layer in order to allow as much light, including UV, as possible to go through the encapsulant layer.

The module according to the present invention comprises a plurality of concatenated polymer sockets, in which each polymer socket accepts and electrically connects a back-contact photovoltaic cell.

Back-contact cells of the disclosed embodiments include MWT cells, BJ cells, IBC cells and EWT cells, and are preferably MWT cells. More preferably, the back-contact cells may be back-contact cells having the backface emitter contacts and the backface collector contacts coated with an electrically conductive soldering composition. Examples of electrically conductive soldering compositions are tin-, tin-lead-, or tin-lead-silver-based soldering compositions. Preferably, the back-contact cells are “symmetrical” back-contact cells, i.e. back-contact cells having the same number of linearly arranged backface emitter contact sets and of linearly arranged backface collector contact sets. More preferably, in the “symmetrical” back-contact cells, the sets of linearly arranged backface emitter contacts and the sets of linearly arranged backface collector contacts alternate.

For the purpose of the present disclosure, the term “linearly arranged contact set” refers to a plurality of the same type of contacts (either collector or emitter) arranged in-line. FIG. 3 shows a symmetrical back-contact cell in which the sets of linearly arranged backface emitter contacts and backface collector contacts alternate, and in which there are the same number of linearly arranged backface emitter contact sets and of linearly arranged backface collector contact sets.

The photovoltaic module according to the invention can optionally comprise a back encapsulant layer, and preferably it comprises a back encapsulant layer. The optional back encapsulant layer in the photovoltaic module according to the present invention may comprise any material as is conventional in the art of photovoltaic modules, i.e. the optional back encapsulant layer may comprise various polymeric materials. The thickness of the optional back encapsulant layer may be in the range of, for example, 100 to 2000 μm, preferably of from 200 to 1000 μm, as is conventional for back encapsulant layers in photovoltaic modules. Preferably, the optional back encapsulant layer comprises ethylene vinyl acetate copolymer, polyvinyl butyral, ethylene alkyl(meth)acrylate copolymer, thermoplastic polyurethane, ionomer, and/or any combinations thereof.

The back sheet in the photovoltaic module according to the present invention may be any back sheet as is conventional in the art of photovoltaic modules, i.e. the back sheet is formed from any rigid material, and the thickness of the back sheet may be in the range of, for example, 500 μm to 2 cm, as is conventional for back sheets of photovoltaic modules. The back sheet can be made of a rigid material, such as glass, polyamide, polycarbonate, polyethylene terephthalate, epoxy resin, acrylate polymer such as polymethylmethacrylate (PMMA), glass fiber reinforced polyamide or polyester, carbon fiber reinforced polymer such as any kind of carbon fiber reinforced polyamide like polyamide 34, 6, 66, 6.66, 6T, 610, 10, 11, 12, glass reinforced polyester such as PET, PEN, PETG, asbestos, and ceramic. In general, the back sheet material may be any material that provides electrical insulation and electrical shock protection. The back sheet may be a single layer of material, or may include more than one layer of material. In the case where the back sheet of the module includes more than one layer of material, it preferably includes a laminate consisting of one or more layers of polyethylene terephthalate sandwiched between polyvinyl fluoride (PVF) layers.

In the photovoltaic module according to the present invention, the back-contact photovoltaic cells are accepted and electrically connected by the polymer sockets of the aforementioned plurality of concatenated polymer sockets, each polymer socket comprising a planar, electrically insulating polymer substrate with perforations coinciding with the backface emitter contacts. At least one electrical conductor is collinear with the perforations of the planar substrate and is adhered to the backface of the planar polymer substrate.

The at least one electrical conductor of each polymer socket, except the last one in each row, is adhered to the frontface of one adjacent polymer socket, so as to be collinear with the at least one set of linearly arranged backface collector contacts of the back-contact photovoltaic cell accepted and electrically connected by the one adjacent polymer socket.

The planar, electrically insulating polymer substrate of the polymer socket may comprise or consist of at least one elastomeric thermoplastic polymer. Suitable elastomeric thermoplastic polymers may be chosen among polymers having a melting temperature (Tₘ) in excess of the temperature applied in the lamination process step of the photovoltaic module manufacturing process. The elastomeric thermoplastic polymers may be chosen, for example among styrenic block copolymers, polyolefin blends, elastomeric alloys such as engineering thermoplastic vulcanizates (ETPVs), ionomers, thermoplastic polyurethanes, thermoplastic copolyester and thermoplastic polyamides. Preferably, the planar electrically insulating polymer substrate comprises a styrenic block copolymer such as styrene-butadiene-styrene block copolymer (SBS), styrene-isoprene-styrene block copolymers (SIS), styrene-ethylene/butylene-styrene block copolymers (SEBS) and styrene-ethylene/propylene-styrene block copolymer (SEPS) or thermoplastic copolyester such as polyester-polyether copolymers.

The planar electrically insulating polymer substrate may be obtainable, for example, by injection molding the elastomeric thermoplastic polymer into the desired shape, by cutting out the desired shape from a sheet of elastomeric thermoplastic polymer, or by laminating different layers of elastomeric thermoplastic polymer together.

The planar electrically insulating polymer substrate of each polymer socket comprises perforations coinciding with the backface emitter contacts of the back-contact photovoltaic cell accepted and electrically connected by the polymer socket comprising the substrate. The perforations may be of any shape such as round, oval or rectangular.

Each polymer socket comprises at least one electrical conductor adhered to the backface of the planar, electrically insulating substrate of the socket. The at least one electrical conductor is collinear with the perforations coinciding with the backface emitter contacts of the back-contact photovoltaic cell accepted and electrically connected by each polymer socket and is adhered to the backface of the planar polymer substrate of each polymer socked.

The perforations in the planar electrically insulating polymer substrate coincide with the backface emitter contacts of the back-contact cell accepted and electrically connected by the polymer socket. Thus, the perforations make it possible to establish an electrical contact between backface emitter contacts of the back-contact cell and the at least one electrical conductor adhered to the backface of the planar electrically insulating polymer substrate by enabling, for example, a soldering connection to be made between the conductor and the emitter contact through the perforations. Conversely, the at least one electrical conductor is electrically insulated from the back-contact cell by the planar, electrically insulating polymer substrate where the polymer substrate is unperforated.

The at least one electrical conductor may be of any electrically conductive material such as for example, copper, iron, aluminum, tin, silver, gold, and alloys thereof. Preferably, the at least one electrical conductor comprises copper or aluminum core surrounded by a electrically conductive soldering composition. Examples of electrically conductive soldering compositions are tin-, tin-lead-, or tin-lead-silver-based soldering compositions. The at least one electrical conductor may be in the form of for example, a flattened wire or ribbon, round wire, printed circuit board (PCB), and preferably are in the form of a flattened wire.

The at least one electrical conductor is collinear with the at least one set of linearly arranged backface emitter contacts of each back-contact cell accepted and electrically connected by each polymer socket, and also with the perforations of the planar substrate coinciding with the at least one set of linearly arranged backface emitter contacts. Thus, the at least one set of linearly arranged backface emitter contacts can be electrically connected to the electrical conductor through the perforations, for example by soldering.

The at least one electrical conductor is located on and adhered to the backface of the planar polymer substrates, i.e. is separated, and electrically insulated, from the back-contact photovoltaic cell located on the frontface of the polymer substrate by the polymer substrate itself where the polymer substrate is unperforated.

The concatenated polymer sockets are formed by interconnecting the polymer sockets such that the at least one electrical conductor of each polymer socket, except the last one in the row, is adhered to the frontface of the planar substrate of one adjacent polymer socket, so as to be collinear with the at least one set of linearly arranged backface collector contacts of the back-contact photovoltaic cell electrically connected and accepted by the adjacent polymer socket. Thus, adjacent polymer sockets are joined, or stringed together, by the at least one electrical conductor which is adhered to the backface and frontface of the polymer substrates of the adjacent polymer sockets.

The at least one electrical conductor of each polymer socket of the concatenations of polymer sockets is adhered to the backface of the planar polymer substrate of each socket such that it is collinear with the perforations coinciding with the at least one set of linearly arranged backface emitter contacts of the back-contact photovoltaic cell accepted and electrically connected by said polymer socket. The electrical conductor is adhered as well to the frontface of the planar polymer substrate of one adjacent polymer socket, except the last one in row, such that it is collinear with the at least one set of linearly arranged backface collector contacts of the back-contact photovoltaic cell accepted and electrically connected by the adjacent polymer socket.

The back-contact photovoltaic cells accepted and electrically connected by adjacent polymer sockets of each concatenation of polymer sockets are rotated by 180° with respect to each other.

The at least one electrical conductor may be adhered to the planar polymer substrate of a polymer socket by a suitable adhesive, or is preferably adhered by heating the electrical conductor to a temperature above the melting temperature (Tₘ) of the polymer of the planar polymer substrate and pressing the electrical conductor against the planar polymer substrate until the temperature of the conductor drops below the melting temperature of the polymer of the planar polymer substrate, and then releasing the previously applied pressure.

The at least one electrical conductor may be heated to a temperature above the melting temperature (Tₘ) of the polymer of the planar polymer substrate by methods known in the art of phovoltaic applications, such as for example induction heating, sonic vibration heating or thermosonic vibration heating, press heating, heated rolls, heated pins or infrared heating.

Preferably, the planar, electrically insulating polymer substrate of each polymer socket further comprises additional perforations coinciding with the backface collector contacts of the back-contact photovoltaic cell accepted and connected by said polymer socket.

In the case where the planar, electrically insulating polymer substrate of each polymer socket comprises perforations coinciding with the at least one set of linearly arranged backface collector contacts, as well as perforations coinciding with the at least one set of linearly arranged backface emitter contacts of the back-contact photovoltaic cell accepted and electrically connected, the perforations coinciding with the set of linearly arranged backface collector contacts of the polymer substrate of one polymer socket are collinear with the perforations coinciding with a set of linearly arranged backface emitter contacts of the polymer substrate of the adjacent polymer socket.

The planar polymer substrate of the polymer socket in the concatenation of interconnected polymer sockets may comprise or consist of at least one elastomeric thermoplastic polymer, or a polymer composition comprising at least one elastomeric thermoplastic polymer. Suitable elastomeric thermoplastic polymers may be chosen among polymers having a melting temperature (Tₘ) in excess of the temperature applied in the lamination process step of the photovoltaic module manufacturing processes, in order to prevent damage to the planar polymer substrate of the polymer socket. The elastomeric thermoplastic polymers may be chosen, for example among styrenic block copolymers, polyolefin blends, elastomeric alloys such as engineering thermoplastic vulcanizates (ETPVs), ionomers, thermoplastic polyurethanes, thermoplastic copolyester and thermoplastic polyamides. Preferably, the planar electrically insulating polymer substrate comprises a styrenic block copolymer such as styrene-butadiene-styrene block copolymer (SBS), styrene-isoprene-styrene block copolymers (SIS), styrene-ethylene/butylene-styrene block copolymers (SEBS) and styrene-ethylene/propylene-styrene block copolymer (SEPS) or thermoplastic copolyester such as polyester-polyether copolymers.

The rotation of the photovoltaic cells by 180° in the plane of the photovoltaic cell with respect to each other has the result that the linearly arranged emitter contact sets of a first photovoltaic cell are aligned, or collinear with the linearly arranged collector contact sets of the adjacent photovoltaic cell, such that they may be electrically connected by at least one electrical conductor that is straight in the direction of concatenation.

The planar, electrically insulating polymer substrate of each polymer socket may be obtained, for example, by injection molding the elastomeric thermoplastic polymer into the desired shape, by cutting out the desired shape from a sheet of elastomeric thermoplastic polymer, or by laminating different layers of elastomeric thermoplastic polymer together.

The planar, electrically insulating polymer substrate of each polymer socket may further have perforations coinciding with the backface collector contacts of the back-contact photovoltaic cells to be accepted and electrically connected by the interconnected polymer sockets of the concatenations.

The interconnection of the polymer sockets to form the concatenation by the at least one electrical conductor may be carried out manually or using automatic equipment. Suitable automatic equipment to interconnect the polymer sockets may be a so-called “tabber-stringer” that has been modified to process the planar, electrically insulating polymer substrates of the polymer sockets. Conventionally, tabber-stringers are used to string together photovoltaic cells, or so-called “H cells”. The tabbing unit generally serves to place and orient the photovoltaic cells, before the stringing unit strings the photovoltaic cells together with electrical conductor by first adhering the electrical conductor to the backface contacts of a first H cell and then adhering said electrical conductor to the frontface contacts of the next H cell in line. Substituting the photovoltaic cells in the tabbing unit of the tabber-stringer with planar, electrically insulating polymer substrates will result in the tabber-stringer interconnecting the polymer substrates such that the backface of a first polymer substrate is connected to the frontface of the next adjacent polymer substrate through at least one electrical conductor by adhering said electrical conductor to the backface of a first polymer substrate as well as to the frontface of the next adjacent polymer substrate.

The tabber-stringer may adhere the electrical conductor to the planar, electrically insulating polymer substrate by heating the conductor to a temperature above the melting temperature of the polymer of the planar polymer substrate and by pressing the electrical conductor against the backface of the planar polymer substrate until the temperature of the conductor drops below the melting temperature of the polymer of the planar polymer substrate, and releasing the previously applied pressure. The heating of the electrical conductor may be achieved by methods known in the art of phovoltaic applications, such as for example induction heating, sonic vibration heating or thermosonic vibration heating, press heating, heated rolls, heated pins, or infra-red heating.

A person skilled in the art of automatic equipment for tab-stringing together photovoltaic cells will be able to modify a conventional tabber-stringer such that it strings together, or interconnects, the planar polymer substrates of the polymer sockets instead of photovoltaic cells by replacing the photovoltaic cells in the tabber-stringer with the planar, electrically insulating polymer substrates of the sockets.

A robot may be used to place the back-contact photovoltaic cells on the planar, electrically insulating polymer substrates such that they can be accepted and electrically connected to the electrical conductors by way of soldering the conductors to the sets of linearly arranged backface emitter contacts and the sets of linearly arranged backface collector contacts of the back-contact photovoltaic cells through the perforations.

In the case where soldering is achieved by heated rolls, the rolls are preferably dented such that the dents push the electrical conductors through the perforations in the planar, electrically insulating polymer substrate such that they can contact the backface emitter contacts of the back-contact cell.

The present invention further provides for a process for the manufacture of a photovoltaic module comprising the steps of assembling a stack by placing an optional back encapsulant layer on a back sheet, placing a plurality of concatenated polymer sockets, each polymer socket having accepted and electrically connected a back-contact photovoltaic cell, on top of the optional back encapsulant layer, placing a front encapsulant layer on top of the back-contact photovoltaic cells and then placing a front sheet on top of the front encapsulant layer. The so assembled stack is then consolidated in a laminating device by heating the stack to a temperature of from 100 to 225° C. and subjecting the heated stack to a mechanical pressure in a direction perpendicular to the plane of the stack and decreasing the ambient pressure in the laminating device to 300 to 1200 mbar, and then cooling the stack to ambient temperature and releasing the mechanical pressure and reestablishing atmospheric pressure in the laminating device. The back-contact photovoltaic cells accepted and electrically connected by adjacent polymer sockets are rotated by 180° with respect to each other. In case no back encapsulant layer is placed on the back sheet, the plurality of concatenated polymer sockets is directly placed on the back sheet.

In the process for the manufacture of the photovoltaic module, the step of assembling a stack by placing an optional back encapsulant layer on a back sheet, placing a plurality of concatenated polymer sockets, each polymer socket having accepted and electrically connected a back-contact photovoltaic cell, on top of the optional back encapsulant layer, placing a front encapsulant layer on top of the back-contact photovoltaic cells and then placing a front sheet on top of the front encapsulant layer may be carried out manually or automatically on an assembling device such as for example a positioning robot. In the process for the manufacture of the photovoltaic module, the step of assembling a stack may be carried out in advance outside the laminating device or may be carried out inside (in-situ) the laminating device, and is preferably carried out inside the laminating device to reduce production cycle times. A laminating device useful in the automatic process for manufacturing the photovoltaic module can be a heat press, for example.

In the process for the manufacture of the photovoltaic module, the step of consolidating the assembled stack in a laminating device is achieved by heating of the stack in the laminating device by, for example, heating the top, lower, or both, platen of the laminating device. The stack is brought to a temperature of from 100 to 225° C., from 100 to 180° C., and in particular of from 120 to 170° C. and more particularly of from 130 to 150° C. Such temperature allows the front and optional back encapsulants to soften, flow around and adhere to the concatenated polymer sockets, each polymer socket having accepted and electrically connected a back-contact photovoltaic cell. Within the limits of the above temperature ranges, the person skilled in the art will choose a temperature setting for the laminating device such that it is high enough to soften or melt the front and optional back encapsulants, but low enough so as to prevent the polymer sockets from softening or melting.

In the process for the manufacture of the photovoltaic module, the step of consolidating the assembled stack in a laminating device is further achieved by subjecting the stack to mechanical pressure perpendicular to the plane of the stack, which pressure may be exerted via the platen of the laminating device. In the process for the manufacture of the photovoltaic module, the step of consolidating the assembled stack in a laminating device is further achieved by decreasing the ambient pressure in the laminating device to 100 to 1200 mbar or 300 to 1200 mbar, in particular to 500 to 1000 mbar and more particularly 600 to 900 mbar. Decreasing the ambient pressure in the laminating device facilitates the removal of air pockets that may have eventually formed between the different layers of the stack during the step of assembling the stack.

In the process for the manufacture of the photovoltaic module, the step of consolidating the assembled stack in a laminating device is finished by cooling the stack to ambient temperature and by releasing the mechanical pressure and reestablishing atmospheric pressure in the laminating device.

1. A photovoltaic module comprising:
a. a front sheet,
b. a front encapsulant layer having opposite first and second sides, the first side of said front encapsulant layer being adhered to said front sheet,
c. a plurality of concatenated polymer sockets arranged in one or more rows, each polymer socket having accepted and electrically connected a back-contact photovoltaic cell, each back-contact photovoltaic cell having at least one set of linearly arranged backface emitter contacts and at least one set of linearly arranged backface collector contacts, said back-contact photovoltaic cells being adhered to the second side of said front encapsulant layer,
d. a back sheet adhered said plurality of concatenated polymer sockets,
wherein each polymer socket comprises
i. a planar, electrically insulating polymer substrate comprising perforations coinciding with the at least one set of linearly arranged backface emitter contacts of the back-contact photovoltaic cell accepted and electrically connected by the polymer socket, said substrate having a frontface and backface on opposite sides of the substrate, the frontface being on the side of the substrate on which the back-contact photovoltaic cell is accepted and electrically connected by the polymer socket, and
ii. at least one electrical conductor being collinear with the perforations of the planar substrate coinciding with the at least one set of linearly arranged backface emitter contacts of the back-contact photovoltaic cell accepted and electrically connected by the socket, the at least one electrical conductor being adhered to the backface of the planar polymer substrate, and
wherein the at least one electrical conductor of each polymer socket, except the last one in each row, is adhered to the frontface of the planar substrate of one adjacent polymer socket, so such as to be collinear with the at least one set of linearly arranged backface collector contacts of the back-contact photovoltaic cell accepted and electrically connected by said one adjacent polymer socket, and wherein the back-contact photovoltaic cells accepted and electrically connected by adjacent polymer sockets are rotated by 180° with respect to each other.

2. The photovoltaic module according to claim 1, wherein the planar, electrically insulating polymer substrate of each polymer socket comprises additional perforations coinciding with the backface collector contacts of the accepted and electrically connected back-contact photovoltaic cell.

3. The photovoltaic module according to claim 1, wherein the planar polymer substrate comprises of at least one elastomeric thermoplastic polymer.

4. The photovoltaic module according to claim 3, wherein the at least one elastomeric thermoplastic polymer is a polyester polyether copolymer.

5. (canceled)

6. The photovoltaic module according to claim 3, wherein the at least one elastomeric thermoplastic polymer is a styrenic block copolymer.

7. The photovoltaic module according to claim 1, wherein the back sheet is adhered to said plurality of concatenated polymer sockets by a back encapsulant layer disposed between said back sheet and said plurality of concatenated polymer sockets.

8. A process for the manufacture of a photovoltaic module comprising the steps of:
a. providing a plurality of back-contact photovoltaic cells each having at least one set of linearly arranged backface emitter contacts and at least one set of linearly arranged backface collector contacts;
b. assembling a concatenation of interconnected polymer sockets each accepting and electrically connecting one of said back-contact photovoltaic cells, including the steps for each polymer socket of
i. providing a planar, electrically insulating polymer substrate having perforations coinciding with the at least one set of linearly arranged backface emitter contacts of the back-contact photovoltaic cell being accepted and electrically connected by the polymer socket, each substrate each having a frontface and backface on opposite sides of the substrate, the frontface being on the side of the substrate for accepting and electrically connecting the back-contact photovoltaic cell by the polymer socket, and
ii. interconnecting said planar, electrically insulating polymer substrate through one or more electrical conductors to form the concatenation of interconnected polymer sockets, such that the backface of each polymer substrate, except the last one in said concatenation, is connected to the frontface of one adjacent polymer substrate by at least one electrical conductor, wherein said conductor is collinear with the perforations of the planar, electrically insulating polymer substrate coinciding with the at least one set of linearly arranged backface emitter contacts of the back-contact photovoltaic cell being accepted and electrically connected by the polymer socket comprising said substrate, and said conductor is collinear with the at least one set of linearly arranged backface collector contacts of the back-contact photovoltaic cell being accepted and electrically connected by the one adjacent polymer socket,
c. electrically connecting the linearly arranged backface emitter contacts and the linearly arranged backface collector contacts of back-contact photovoltaic cells of adjacent polymer sockets by said at least one electrical conductor interconnecting adjacent polymer sockets of the concatenation of interconnected polymer sockets,
d. accepting and electrically connecting said plurality of back-contact protovoltaic cells in the polymer sockets of said concatenation of interconnected polymer sockets, wherein the back-contact photovoltaic cells accepted and electrically connected by adjacent polymer sockets are rotated by 180° with respect to each other,
e. assembling a stack by
i. providing a back sheet
ii. placing the concatenated polymer sockets with the accepted and electrically connected a back-contact photovoltaic cells over the back sheet and adhering the polymer sockets to the back sheet,
iii. placing a front encapsulant layer on top of the back-contact photovoltaic cells,
iv. placing a front sheet on top of the front encapsulant layer,
f. consolidating the so assembled stack in a laminating device by
i. heating the stack to a temperature of from 100 to 225° C.,
ii. subjecting the heated stack to a mechanical pressure in a direction perpendicular to the plane of the stack and decreasing the ambient pressure in the laminating device to 300 to 1200 mbar, and
iii. cooling the stack to ambient temperature and releasing the mechanical pressure and reestablishing atmospheric pressure in the laminating device.

9. The process for the manufacture of a photovoltaic module of claim 8, wherein the back sheet is adhered to said plurality of concatenated polymer sockets by a back encapsulant layer disposed between said back sheet and said plurality of concatenated polymer sockets.

10. The process according to claim 8, wherein the interconnecting said planar, electrically insulating polymer substrates through one or more electrical conductors to form the concatenation of interconnected polymer sockets through one or more electrical conductors is conducted on tabber-stringer automatic equipment.
